(19) United States
(12) Patent Application Publication
(10) Pub. No.: US 2024/0405093 A1
(43) Pub. Date: Dec. 5, 2024

(54) CRYSTALLIZATION TEMPERATURE REDUCTION OF HIGH-K DIELECTRIC LAYER

(71) Applicant: Taiwan Semiconductor Manufacturing Co., Ltd., Hsinchu (TW)

(72) Inventors: Shen-Yang LEE, Miaoli County (TW); Hsiang-Pi CHANG, New Taipei City (TW); Huang-Lin CHAO, HSINCHU CITY (TW); Pinyen LIN, Rochester, NY (US)

(73) Assignee: Taiwan Semiconductor Manufacturing Co., Ltd., Hsinchu (TW)

(21) Appl. No.: 18/328,502

(22) Filed: Jun. 2, 2023

(51) Int. Cl. H01L 29/51; H01L 21/3115; H01L 29/06; H01L 29/423; H01L 29/66; H01L 29/775

(52) U.S. Cl. CPC H01L 29/513; H01L 21/3115; H01L 29/0673; H01L 29/42392; H01L 29/66439; H01L 29/775

(57) ABSTRACT

The present disclosure describes forming a crystalline high-k dielectric layer at a reduced crystallization temperature in a semiconductor device. The method includes forming a channel structure on a substrate, forming an interfacial layer on the channel structure, forming a first high-k dielectric layer on the interfacial layer, forming dipoles in the first high-k dielectric layer with a dopant, and forming a second high-k dielectric layer on the first high-k dielectric layer. The dopant includes a first metal element. The second high-k dielectric layer includes a second metal element different from the first metal element.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs and fin field effect transistors (finFETs). Such scaling down has increased the complexity of semiconductor manufacturing processes and increased the difficulty of process control in the semiconductor devices.

### BRIEF DESCRIPTION OF THE DRAWINGS

Aspects of the present disclosure are best understood from the following detailed description when read with the accompanying figures.

FIG. 1 illustrates an isometric view of a semiconductor device having a crystalline high-k dielectric layer fabricated at a reduced crystallization temperature, in accordance with some embodiments.

FIG. 2 illustrates a cross-sectional view of a semiconductor device having a crystalline high-k dielectric layer fabricated at a reduced crystallization temperature, in accordance with some embodiments.

FIG. 3 is a flow diagram of a method for fabricating a crystalline high-k gate dielectric layer in a semiconductor device at a reduced crystallization temperature, in accordance with some embodiments.

FIGS. 4-12 illustrate cross-sectional views of a semiconductor device having a crystalline high-k gate dielectric layer fabricated at a reduced crystallization temperature at various stages of its fabrication, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 20% of the value (e.g., ±1%, ±2%, ±3%, ±4%, ±5%, ±10%, ±20% of the value). These values are merely examples and are not intended to be limiting. The terms “about” and “substantially” can refer to a percentage of the values as interpreted by those skilled in relevant art(s) in light of the teachings herein.

With increasing demand for lower power consumption, higher performance, and smaller semiconductor devices, dimensions of semiconductor devices continue to scale down. The continuous scaling down of device dimensions and the increasing demand for device performance may require various process and material improvements, which can have multiple challenges. For example, gate dielectric layers of a nanostructure transistor can include an interfacial layer and a high-k dielectric layer. The high-k dielectric layer can include high-k dielectric material to reduce gate dielectric layer dimensions and increase gate control. The term “high-k” can refer to a high dielectric constant. In the field of semiconductor device structures and manufacturing processes, high-k can refer to a dielectric constant that is greater than the dielectric constant of silicon oxide (e.g., greater than about 3.9). The high-k dielectric material can be crystallized at a high temperature (e.g., about 800° C. to about 1000° C.) into a cubic phase or other crystalline phases to increase dielectric constant (i.e., k value) and reduce leakage current. However, the high temperature of the crystallization process can create defects at the interface of the interfacial layer and high-k dielectric layer, change dopant profiles in the channel and source/drain (S/D) regions of the nanostructure transistor, and decrease the stress between the channel and S/D regions. S/D region(s) may refer to a source or a drain, individually or collectively dependent upon the context.

Various embodiments in the present disclosure provide example methods for forming a crystalline high-k dielectric layer at a reduced crystallization temperature in a semiconductor device (e.g., a nanostructure transistor) and/or other semiconductor devices in an integrated circuit (IC). In some embodiments, a channel structure can be formed on a substrate and an interfacial layer can be formed on the channel structure. A first high-k dielectric layer can be formed on the interfacial layer and can be doped with a first dopant. The first dopant can include a first metal element to form dipoles in the first high-k dielectric layer and/or at the interface between the interfacial layer and the first high-k dielectric layer. A second high-k dielectric layer can be formed on the first high-k dielectric layer and the second high-k dielectric layer can include a second metal element different from the first metal element. The second metal element can diffuse into the first high-k dielectric layer as a second dopant during a subsequent anneal process and can reduce the crystallization temperature of the first high-k dielectric layer. In some embodiments, the crystallization temperature can be reduced to about 500° C. to about 700° C. Accordingly, the first high-k dielectric layer can be crystallized at a lower temperature and the thermal budget of the manufacturing process can be reduced. Additionally, the defects at the interface of the interfacial layer and the first high-k dielectric layer can be reduced, the dopant profile change in the channel and S/D regions of the semiconductor device can be minimized, and the stress between the channel and S/D regions can be maintained.

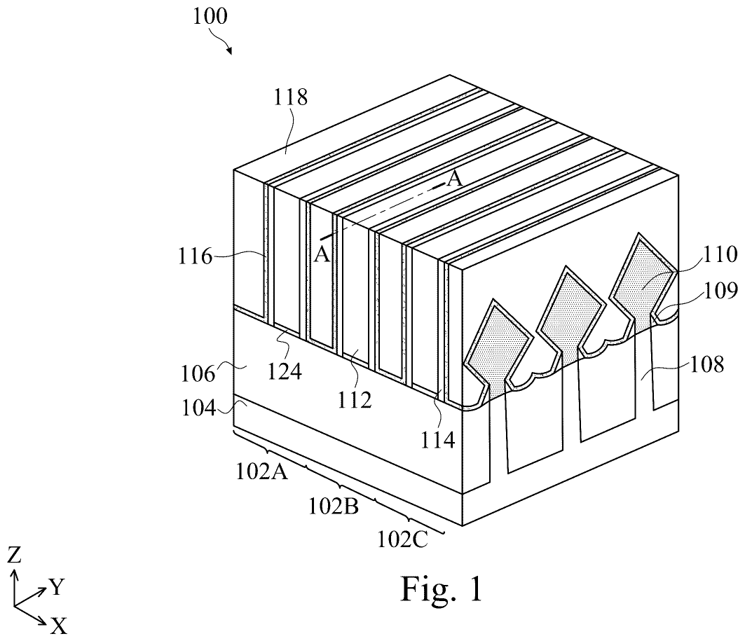

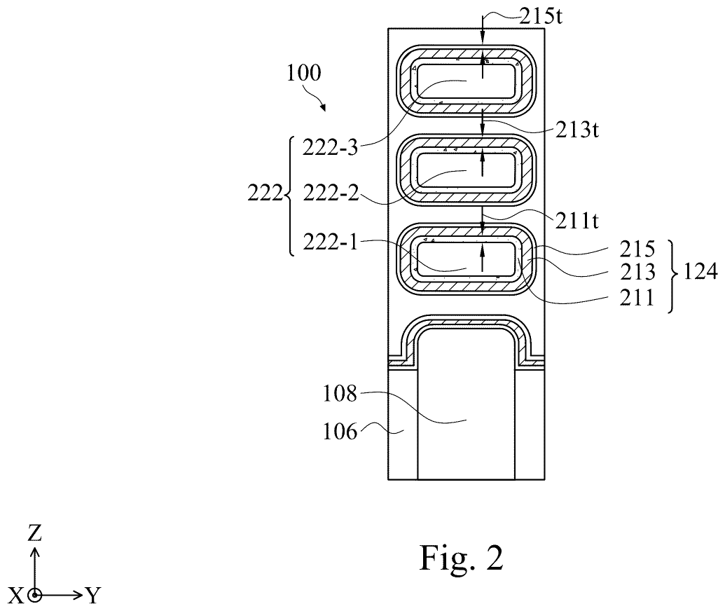

FIG. 1 illustrates an isometric view of a semiconductor device 100 having a crystalline high-k dielectric layer fabricated at a reduced crystallization temperature, in accordance with some embodiments. FIG. 2 illustrates a partial cross-sectional view of semiconductor device 100 across line A-A shown in FIG. 1, in accordance with some embodiments. In some embodiments, semiconductor device 100 can include transistors 102A-102C, as shown in FIG. 1. In some embodiments, transistors 102A-102C can include nanostructure transistors. The nanostructure transistors can include the finFETs, the gate-all-around field effect transistor (GAA FET), the nanosheet transistor, the nanowire transistor, the multi-bridge channel transistor, the nano-ribbon transistor, and other similar structured transistors. The nanostructure transistors can provide a channel in a stacked nanosheet/nanowire configuration.

In some embodiments, transistors 102A-102C can be n-type field-effect transistors (NFETs). In some embodiments, transistors 102A-102C can be p-type nanostructure field-effect transistors (PFETs). In some embodiments, any of transistors 102A-102C can be an NFET or a PFET. Though FIG. 1 shows three transistors, semiconductor device 100 can have any number of transistors. In addition, semiconductor device 100 can be incorporated into an IC through the use of other structural components, such as conductive vias, conductive lines, dielectric layers, passivation layers, and interconnects, which are not shown for simplicity. The discussion of elements of transistors 102A-102C with the same annotations applies to each other, unless mentioned otherwise. And like reference numerals generally indicate identical, functionally similar, and/or structurally similar elements.

Referring to FIGS. 1 and 2, semiconductor device 100 having transistors 102A-102C can be formed on a substrate 104 and can be isolated by shallow trench isolation (STI) regions 106. Each of transistors 102A-102C can include fin structures 108, sidewall spacers 109, gate dielectric layer 124, gate structures 112, gate spacers 114, S/D structures 110, etch stop layer (ESL) 116, and interlayer dielectric (ILD) layer 118. In some embodiments, as shown in FIG. 2, nanostructure transistors 102A-102C can have nanostructures 222-1, 222-2, and 222-3 (collectively referred to as “nanostructures 222”) on fin structures 108.

Referring to FIG. 1, substrate 104 can include a semiconductor material, such as silicon. In some embodiments, substrate 104 includes a crystalline silicon substrate (e.g., wafer). In some embodiments, substrate 104 includes (i) an elementary semiconductor, such as germanium; (ii) a compound semiconductor including silicon carbide, gallium arsenide, gallium phosphide, indium phosphide, indium arsenide, and/or indium antimonide; (iii) an alloy semiconductor including silicon germanium carbide, silicon germanium, gallium arsenic phosphide, and/or aluminum gallium arsenide; or (iv) a combination thereof. Further, substrate 104 can be doped depending on design requirements (e.g., p-type substrate or n-type substrate). In some embodiments, substrate 104 can be doped with p-type dopants (e.g., boron, indium, aluminum, or gallium) or n-type dopants (e.g., phosphorus or arsenic).

STI regions 106 can provide electrical isolation between transistors 102A-102C and from neighboring transistors (not shown) on substrate 104 and/or neighboring active and passive elements (not shown) integrated with or deposited on substrate 104. STI regions 106 can be made of a dielectric material. In some embodiments, STI regions 106 can include silicon oxide, silicon nitride, silicon oxynitride, fluorine-doped silicate glass (FSG), a low-k dielectric material, and/or other suitable insulating materials. In some embodiments, STI regions 106 can include a multi-layered structure.

Referring to FIGS. 1 and 2, nanostructures 222 and fin structures 108 can be formed on patterned portions of substrate 104. Embodiments of the nanostructures and fin structures disclosed herein may be patterned by any suitable method. For example, the nanostructures and fin structures may be patterned using one or more photolithography processes, including double-patterning or multi-patterning processes. Double-patterning or multi-patterning processes can combine photolithography and self-aligned processes, forming patterns that have, for example, pitches smaller than what is otherwise obtainable using a single, direct photolithography process. For example, a sacrificial layer is formed over a substrate and patterned using a photolithography process. Spacers can be formed alongside the patterned sacrificial layer using a self-aligned process. The sacrificial layer is then removed, and the remaining spacers can then be used to pattern the nanostructures and fin structures.

As shown in FIGS. 1 and 2, nanostructures 222 and fin structures 108 can extend along an X-axis and through transistors 102A-102C. In some embodiments, nanostructures 222 and fin structures 108 can be disposed on substrate 104. Nanostructures 222 can include a set of nanostructures 222-1, 222-2, and 222-3, which can be in the form of nanosheets, nanowires, or nano-ribbons. Each of nanostructures 222 can act as a channel structure and form a channel region underlying gate structures 112 of transistors 102A-102C. In some embodiments, nanostructures 222 and fin structures 108 can include semiconductor materials similar to or different from substrate 104. In some embodiments, nanostructures 222 and fin structures 108 can include silicon. In some embodiments, nanostructures 222 and fin structures 108 can include silicon germanium. The semiconductor materials of nanostructures 222 and fin structures 108 can be undoped or can be in-situ doped during their formation process. In some embodiments, as shown in FIG. 2, nanostructures 222 under gate structures 112 can form channel regions of semiconductor device 100 and represent current carrying channel structures of semiconductor device 100. Though three layers of nanostructures 222 are shown in FIG. 2, transistors 102A-102C can have any number of nanostructures 222.

In some embodiments, nanostructures 222 can have a thickness along a Z-axis ranging from about 5 nm to about 8 nm. In some embodiments, nanostructures 222 can have a width along a Y-axis ranging from about 15 nm to about 50 nm. In some embodiments, a spacing between adjacent nanostructures 222 along a Z-axis can range from about 8 nm to about 12 nm.

Referring to FIG. 2, gate dielectric layer 124 can be multi-layered structures and can be formed on nanostructures 222, fin structures 108, and STI regions 106. As shown in FIG. 2, gate dielectric layer 124 can include an interfacial layer 211, a first high-k dielectric layer 213, and a second high-k dielectric layer 215. In some embodiments, gate dielectric layer 124 can include first high-k dielectric layer 213 in direct contact with nanostructures 222. In some embodiments, interfacial layer 211 can include silicon oxide formed by a deposition process or an oxidation process. In some embodiments, interfacial layer 211 can have a thickness ranging from about 0.1 nm to about 1.5 nm.

In some embodiments, first high-k dielectric layer 213 can include hafnium oxide, zirconium oxide, or other suitable high-k dielectric materials. In some embodiments, first high-k dielectric layer 213 can be crystalline and can include a crystalline high-k dielectric material. The crystalline high-k dielectric material can have a higher dielectric constant than the amorphous high-k dielectric material. In some embodiments, the crystalline high-k dielectric material can have a cubic crystalline phase or other crystalline phases. In some embodiments, first high-k dielectric layer 213 doped with the second dopant can have a higher dielectric constant. In some embodiments, first high-k dielectric layer 213 can have a thickness 213t ranging from about 1 nm to about 5 nm. If thickness 213t is greater than about 5 nm, gate capacitance may decrease and device performance may decrease. If thickness 213t is less than about 1 nm, first high-k dielectric layer 213 may not be uniform and may have increased leakage current.

In some embodiments, first high-k dielectric layer 213 can be doped with a first dopant to form dipoles in first high-k dielectric layer 213 and/or at the interface between interfacial layer 211 and first high-k dielectric layer 213. In some embodiments, the dipoles can be formed by diffusing the first dopant from a dipole source layer formed on first high-k dielectric layer 213. In some embodiments, the first dopant can include a first metal element having high chemical affinity for silicon or germanium and can form dopant dipoles with silicon or germanium at the interface under a thermal condition (e.g., a thermal anneal). The amount of the first dopant diffused to the interface and the amount of the dipoles formed around the interface can tune the threshold voltage (Vi) of transistors 102A-102C. In some embodiments, the dopant dipoles can be formed prior to the formation of second high-k dielectric layer 215. In some embodiments, the dopant dipoles can be formed after the formation of second high-k dielectric layer 215.

In some embodiments, depending upon the nature of the first dopant used, the dipoles formed at the interface can attract electrons (or holes) in the channel under gate dielectric layer 124 and thus decrease Vi for the NFET (or the PFET). The dipoles at the interface can also repel holes (or electrons) in the channel and thus increase Vₜ for the PFET (or the NFET). The dipoles at the interface between interfacial layer 211 and first high-k dielectric layer 213 can cause more Vₜ shift than the dipoles in first high-k dielectric layer 213 due to a smaller distance between the interface and the channel and also due to less dipole charge shielding by the lower k interfacial layer material of interfacial layer 211 than by the higher k material of first high-k dielectric layer 213. In some embodiments, the dipole source layer used for NFET Vi tuning can include a metal element different from the metal element in the dipole source layer used for PFET Vₜ tuning. In some embodiments, the dipole source layer used for NFET Vₜ tuning can include lanthanum oxide (La₂O₃), lutetium oxide (Lu₂O₃), yttrium oxide (Y₂O₃), thulium oxide (Tm₂O₃), scandium oxide (Sc₂O₃), gadolinium oxide (Gd₂O₃), or other suitable rare earth metal oxides, alkaline earth metal oxide, and transition metal oxides. In some embodiments, the dipole source layer used for PFET Vₜ tuning can include zinc oxide (ZnO), germanium oxide (GeOₓ), aluminum oxide (AlOₓ), titanium oxide (TiOₓ), vanadium oxide (VOₓ), or other suitable rare earth metal oxides, alkaline earth metal oxide, and transition metal oxides. In some embodiments, the dipole source layer can be removed after doping the first dopant in first high-k dielectric layer 213.

In some embodiments, second high-k dielectric layer 215 can be disposed on first high-k dielectric layer 213 and can include a high-k dielectric material different from first high-k dielectric layer 213. In some embodiments, second high-k dielectric layer 215 can be deposited on both NFET and PFET devices. In some embodiments, the high-k dielectric material in second high-k dielectric layer 215 can include Lu₂O₃, Y₂O₃, Tm₂O₃, erbium oxide (Er₂O₃), Gd₂O₃, or other suitable transition metal oxides. In some embodiments, the high-k dielectric material in second high-k dielectric layer 215 can include a second metal element different from the first metal element. The second metal element can diffuse into first high-k dielectric layer 213 during subsequent anneal processes to form a second dopant in first high-k dielectric layer 213. In some embodiments, one metal element in a dielectric material can have a dopant solubility limit. To avoid reaching the dopant solubility limit of one metal element, the first and second metal elements can be different. In some embodiments, a peak of the second dopant profile in first high-k dielectric layer 213 can be located at a bottom portion, a middle portion, or a top portion of first high-k dielectric layer 213. In some embodiments, the second metal element can include lutetium, yttrium, thulium, erbium, or gadolinium. In some embodiments, the second metal element can include lutetium or yttrium. In some embodiments, the second metal element can include lutetium or yttrium without including thulium, erbium, or gadolinium.

In some embodiments, a concentration of the second metal element in first high-k dielectric layer 213 can range from about 5% to about 25%. With second high-k dielectric layer 215 on first high-k dielectric layer 213 and the second metal element in first high-k dielectric layer 213, crystallization temperature of first high-k dielectric layer 213 can be reduced to about 500° C. to about 700° C. If the concentration of the second metal element in first high-k dielectric layer 213 is less than about 5%, the crystallization temperature of first high-k dielectric layer 213 may not be reduced. If the concentration of the second metal element in first high-k dielectric layer 213 is greater than about 25%, defects in first high-k dielectric layer 213 may increase due to higher dopant concentration than the dopant solubility limit. With the reduced crystallization temperature of first high-k dielectric layer 213, the defects at the interface of interfacial layer 211 and first high-k dielectric layer 213 can be reduced, the dopant profile change in nanostructures 222 and S/D structures 110 can be minimized, and the stress between nanostructures 222 and S/D structures 110 can be maintained.

In some embodiments, second high-k dielectric layer 215 can have a lower dielectric constant than first high-k dielectric layer 213. In some embodiments, second high-k dielectric layer 215 can have a thickness 215t ranging from about 1 Å to about 5 Å. In some embodiments, a ratio of thickness 213t to thickness 215t can range from about 2 to about 50. If thickness 215t is greater than about 5 Å or the ratio is less than about 2, the dielectric constant of gate dielectric layer 124 may be reduced. If thickness 215t is less than about 1 Å or the ratio is greater than about 50, the concentration of the second metal element in first high-k dielectric layer 213 may be less than about 5% and the crystallization temperature of first high-k dielectric layer 213 may not be reduced.

S/D structures 110 can be disposed on substrate 104 and on opposing sides of gate structures 112. S/D structures 110 can function as S/D regions of transistors 102A-102C. In some embodiments, S/D structures 110 can have any geometric shape, such as a polygon, an ellipsis, and a circle. In some embodiments, S/D structures 110 can include an epitaxially-grown semiconductor material, such as silicon (e.g., the same material as substrate 104). In some embodiments, the epitaxially-grown semiconductor material can include an epitaxially-grown semiconductor material different from the material of substrate 104, such as silicon germanium, and imparts a strain on the channel regions under gate structures 112. Since the lattice constant of such epitaxially-grown semiconductor material is different from the material of substrate 104, the channel regions are strained to increase carrier mobility in the channel regions of semiconductor device 100. The epitaxially-grown semiconductor material can include: (i) a semiconductor material, such as germanium and silicon; (ii) a compound semiconductor material, such as gallium arsenide and aluminum gallium arsenide; or (iii) a semiconductor alloy, such as silicon germanium and gallium arsenide phosphide.

In some embodiments, S/D structures 110 can include silicon and can be in-situ doped during an epitaxial growth process using n-type dopants, such as phosphorus and arsenic. In some embodiments, S/D structures 110 can include silicon, silicon germanium, germanium, or III-V materials (e.g., indium antimonide, gallium antimonide, or indium gallium antimonide) and can be in-situ doped during an epitaxial growth process using p-type dopants, such as boron, indium, and gallium. In some embodiments, S/D structures 110 can include one or more epitaxial layers, where each epitaxial layer can have different compositions.

In some embodiments, as shown in FIGS. 1 and 2, gate structures 112 can be disposed on gate dielectric layer 124. In some embodiments, gate structures 112 can include one or more work function metal layers and a metal fill. The one or more work function metal layers can include work function metals to tune the threshold voltage (Vₜ) of transistors 102A-102C. In some embodiments, gate structures 112 for NFET and PFET devices can have the same work-function metal. In some embodiments, gate structures 112 for NFET and PFET devices can have different work-function metals. In some embodiments, the work-function metals for NFET and PFET devices can be adjusted in response to the second dopant in first high-k dielectric layer 213. In some embodiments, as shown in FIG. 2, each of nanostructures 222 can be wrapped around by gate structures 112, for which gate structures 112 can be referred to as “gate-all-around (GAA) structures” and transistors 102A-102C can also be referred to as “GAA FETs 102A-102C.” The one or more work function metal layers can wrap around nanostructures 222 and can include work function metals to tune the Vₜ of transistors 102A-102C. In some embodiments, transistors 102A-102C can include any number of work function metal layers for Vₜ tuning (e.g., ultra-low Vₜ, low Vₜ, and standard Vₜ).

In some embodiments, NFETs 102A-102C can include n-type work function metal layers. The n-type work function metal layers can include aluminum, titanium aluminum, titanium aluminum carbon, tantalum aluminum, tantalum aluminum carbon, tantalum silicon carbide, hafnium carbide, silicon, titanium nitride, titanium silicon nitride, or other suitable work function metals. In some embodiments, PFETs 102A-102C can include p-type work function metal layers. The p-type work function metal layers can include titanium nitride, titanium silicon nitride, tantalum nitride, tungsten carbon nitride, tungsten, molybdenum, or other suitable work function metals. In some embodiments, the work function metal layers can include a single metal layer or a stack of metal layers. The stack of metal layers can include work function metals having work-function values equal to or different from each other. In some embodiments, the metal fill can include titanium, tantalum, aluminum, cobalt, tungsten, nickel, ruthenium, or other suitable conductive materials.

Referring to FIG. 1, gate spacers 114 can be disposed on sidewalls of gate structures 112, and sidewall spacers 109 can be disposed on sidewalls of fin structures 108. Gate spacers 114 and sidewall spacers 109 can include insulating materials, such as silicon oxide, silicon nitride, silicon oxynitride, silicon carbonitride, silicon oxycarbide, silicon oxycarbonitride, a low-k material, and a combination thereof. Gate spacers 114 and sidewall spacers 109 can include a single layer or a stack of insulating layers. Gate spacers 114 and sidewall spacers 109 can have a low-k material with a dielectric constant less than about 3.9 (e.g., about 3.5, about 3.0, or about 2.8).

ESL 116 can be disposed on STI regions 106, S/D structures 110, and sidewalls of gate spacers 114 and sidewall spacers 109. ESL 116 can be configured to protect STI regions 106, S/D structures 110, and gate structures 112 during the formation of S/D contact structures on S/D structures 110. In some embodiments, ESL 116 can include, for example, silicon oxide, silicon nitride, silicon oxynitride, silicon carbide, silicon carbonitride, boron nitride, silicon boron nitride, silicon carbon boron nitride, or a combination thereof.

ILD layer 118 can be disposed on ESL 116 over S/D structures 110 and STI regions 106. ILD layer 118 can include a dielectric material deposited using a deposition method suitable for flowable dielectric materials. For example, flowable silicon oxide can be deposited using flowable chemical vapor deposition (FCVD). In some embodiments, the dielectric material can include silicon oxide.

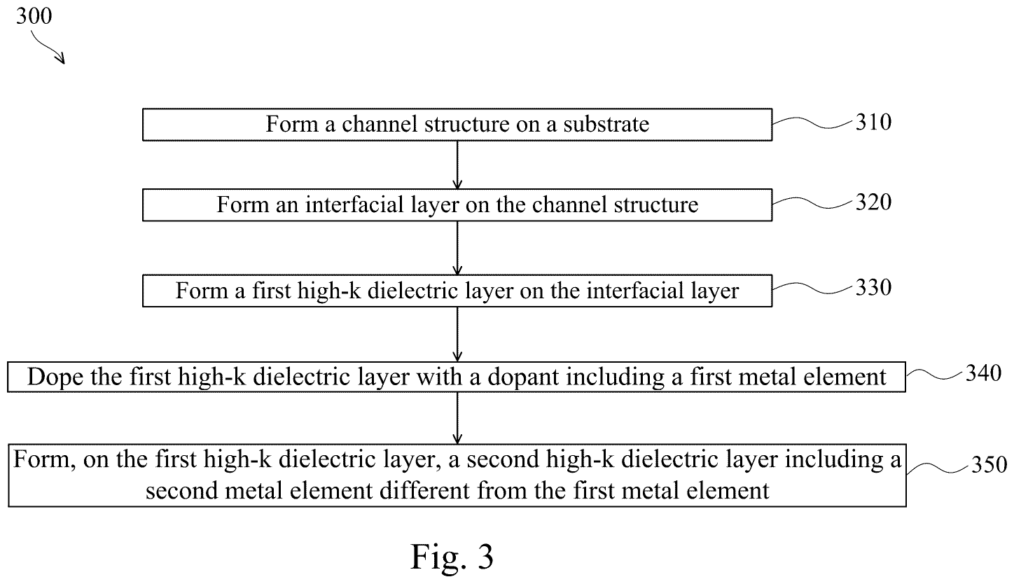

FIG. 3 is a flow diagram of a method 300 for fabricating semiconductor device 100 having a crystalline high-k dielectric layer fabricated at a reduced crystallization temperature, in accordance with some embodiments. Method 300 may not be limited to nanostructure transistor devices and can be applicable to other devices that would benefit from the crystalline high-k dielectric layer fabricated at a reduced crystallization temperature. Additional fabrication operations may be performed between various operations of method 300 and may be omitted merely for clarity and ease of description. Additional processes can be provided before, during, and/or after method 300; one or more of these additional processes are briefly described herein. Moreover, not all operations may be needed to perform the disclosure provided herein. Additionally, some of the operations may be performed simultaneously or in a different order than shown in FIG. 3. In some embodiments, one or more other operations may be performed in addition to or in place of the presently-described operations.

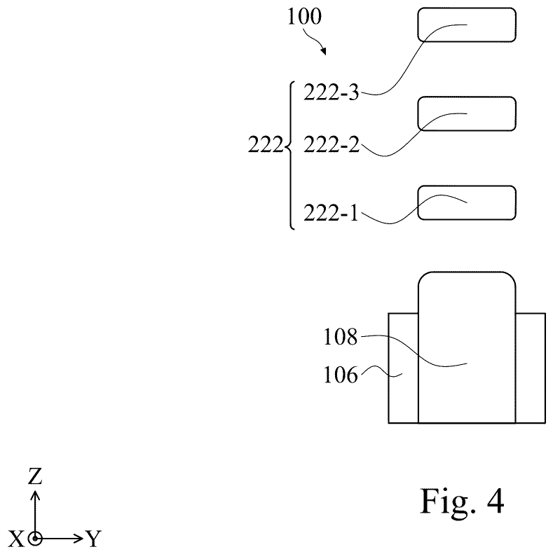

For illustrative purposes, the operations illustrated in FIG. 3 will be described with reference to the example fabrication process for fabricating semiconductor device 100 as illustrated in FIGS. 4-12. FIGS. 4-12 illustrate partial cross-sectional views of semiconductor device 100 having a crystalline high-k gate dielectric layer fabricated at a reduced crystallization temperature at various stages of its fabrication, in accordance with some embodiments. Elements in FIGS. 4-12 with the same annotations as elements in FIGS. 1 and 2 are described above.

In referring to FIG. 3, method 300 begins with operation 310 and the process of forming a channel structure on a substrate. For example, as shown in FIGS. 1, 2, and 4, nanostructures 222-1, 222-2, and 222-3 can be formed on substrate 104 and can act as channel structures in semiconductor device 100. FIG. 4 illustrates a partial cross-sectional view of semiconductor device 100 along line A-A as shown in FIG. 1, in accordance with some embodiments. In some embodiments, nanostructures 222 can be epitaxially grown on substrate 104 and stacked with additional nanostructures (not shown) in an alternate configuration. Nanostructures 222 and the additional nanostructures can be patterned by double- or multi-patterning processes described above. The additional nanostructures can include semiconductor materials different from nanostructures 222. For example, nanostructures 222 can include silicon and the additional nanostructures can include silicon germanium. The semiconductor materials of nanostructures 222 can be undoped or can be in-situ doped during their formation process. The additional nanostructures can be removed in subsequent processes to form nanostructures 222 stacked vertically and separated from each other, as shown in FIG. 4. In some embodiments, nanostructures 222 can be in the form of nanosheets, nanowires, or nano-ribbons. In some embodiments, nanostructures 222 and fin structures 108 can include semiconductor materials similar to or different from substrate 104.

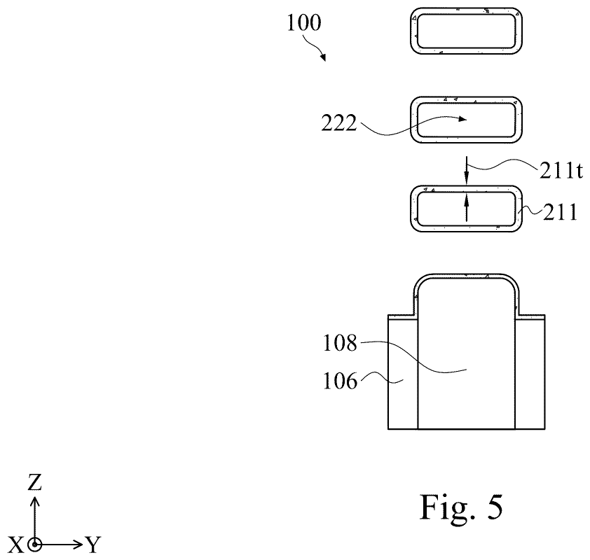

Referring to FIG. 3, in operation 320, an interfacial layer is formed on the channel structure. For example, as shown in FIG. 5, interfacial layer 211 can be formed on nanostructures 222. In some embodiments, interfacial layer 211 can include silicon oxide formed by a deposition process or an oxidation process. If interfacial layer 211 is formed by the deposition process, interfacial layer 211 can be formed on nanostructures 222, fin structures 108, and STI regions 106. If interfacial layer 211 is formed by the oxidation process, interfacial layer 211 can be formed on nanostructures 222 and fin structures 108. In some embodiments, interfacial layer 211 can have a thickness ranging from about 0.1 nm to about 1.5 nm. In some embodiments, interfacial layer 211 can be optional and can be omitted.

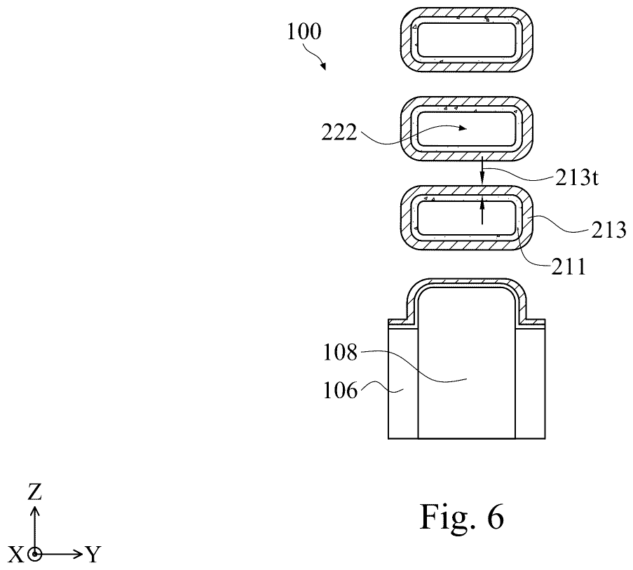

Referring to FIG. 3, in operation 330, a first high-k gate dielectric layer is formed on the interfacial layer. For example, as shown in FIG. 6, first high-k dielectric layer 213 can be formed on interfacial layer 211. In some embodiments, first high-k dielectric layer 213 can be deposited on interfacial layer 211 over nanostructures 222, fin structures 108, and STI regions 106. In some embodiments, first high-k dielectric layer 213 can be conformally deposited at a temperature from about 200° C. to about 400° C. by atomic layer deposition (ALD), chemical vapor deposition (CVD), or other suitable deposition methods. In some embodiments, first high-k dielectric layer 213 can be amorphous after deposition. In some embodiments, first high-k dielectric layer 213 can include hafnium oxide, zirconium oxide, or other suitable high-k dielectric materials. In some embodiments, thickness 213t of first high-k dielectric layer 213 can range from about 1 nm to about 5 nm. If thickness 213t is greater than about 5 nm, gate capacitance may decrease and device performance may decrease. If thickness 213t is less than about 1 nm, first high-k dielectric layer 213 may not be uniform and may have increased leakage current.

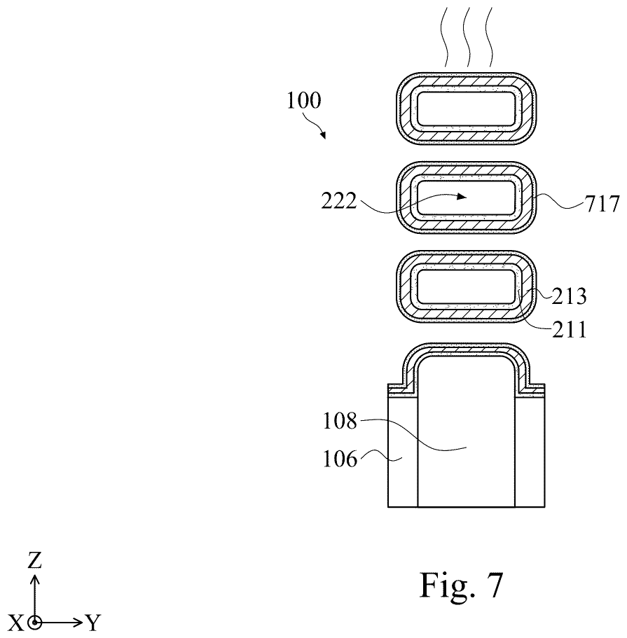

Referring to FIG. 3, in operation 340, the first high-k gate dielectric layer is doped with a dopant including a first metal element to form dipoles. For example, as shown in FIG. 7, a dipole source layer 717 can be formed on first high-k dielectric layer 213 to dope first high-k dielectric layer 213. In some embodiments, dipole source layer 717 can be deposited on first high-k dielectric layer 213 by ALD, CVD, or other suitable deposition methods with a thickness ranging from about 3 Å to about 30 Å. In some embodiments, for NFET devices, dipole source layer 717 can include La₂O₃, Lu₂O₃, Y₂O₃, Tm₂O₃, Sc₂O₃, Gd₂O₃, or other suitable rare earth metal oxides, alkaline earth metal oxide, and transition metal oxides. In some embodiments, for PFET devices, dipole source layer 717 can include ZnO, GeOₓ, AlOₓ, TiOₓ, VOₓ, or other suitable rare earth metal oxides, alkaline earth metal oxide, and transition metal oxides. In some embodiments, dipole source layer 717 for NFET and PFET devices can include different dopants having different metal elements.

In some embodiments, the deposition of dipole source layer 717 can be followed by a thermal treatment to dope first high-k dielectric layer 213 and interfacial layer 211. For example, as shown in FIG. 7, dipole source layer 717 can be treated with an isothermal anneal at an annealing temperature ranging from about 500° C. to about 800° C. The isothermal anneal can be performed in an inert gas environment, such as nitrogen and argon, at a pressure ranging from about 10 mtorr to about 5 torr for about 3 s to about 100 s. With the thermal treatment, the first metal element in dipole source layer 717 can diffuse and form dipoles in first high-k dielectric layer 213 and interfacial layer 211.

Depending upon the nature of the dopant used, the dipoles in first high-k dielectric layer 213 and interfacial layer 211 can attract electrons (or holes) in the channel under gate dielectric layer 124 and thus decrease Vₜ for the NFET (or decrease Vₜ for the PFET). The dipoles in first high-k dielectric layer 213 and interfacial layer 211 can also repel holes in the channel and thus increase Vₜ for the PFET (or increase Vₜ for the NFET). In some embodiments, the dipoles at interfacial layer 211 can cause more Vₜ shift than the dipoles in the high-k dielectric layer due to a smaller distance between the interfacial layer and the channel and also due to less dipole charge shielding by the lower k dielectric material of interfacial layer 211 than by the higher k dielectric material of first high-k dielectric layer 213. In some embodiments, the first metal element of the dopants for NFET and PFET devices can be different and the dipoles formed in first high-k dielectric layer 213 and interfacial layer 211 can be different.

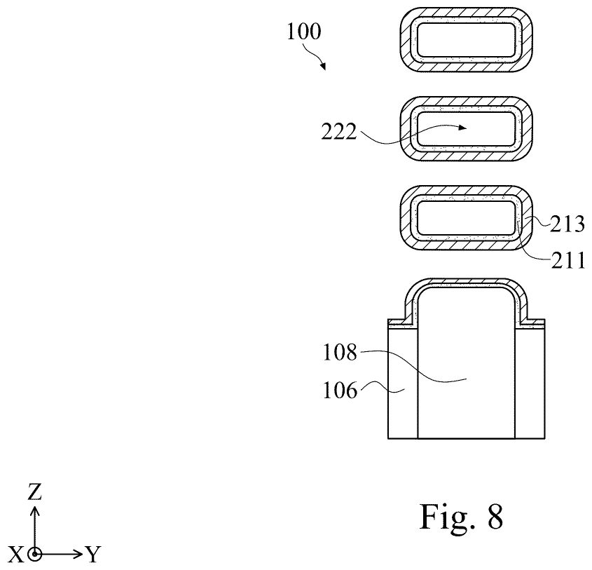

In some embodiments, the doping of first high-k dielectric layer 213 and interfacial layer 211 can be followed by removal of dipole source layer 717. For example, as shown in FIG. 8, dipole source layer 717 can be removed from first high-k dielectric layer 213. a wet chemical etching process can remove dipole source layer 717 at a temperature range from about 25° C. to about 300° C. after the doping process. In some embodiments, dipole source layer 717 can be deposited on NFET devices first to form n-type dipoles with one metal element and dipole source layer 717 can be removed afterwards. Subsequently, dipole source layer 717 can be deposited on PFET devices to form p-type dipoles with a different metal element and dipole source layer 717 can be removed afterwards. NFET (or PFET) devices can be covered with a mask layer during the process of forming dipoles in PFET (or NFET) devices.

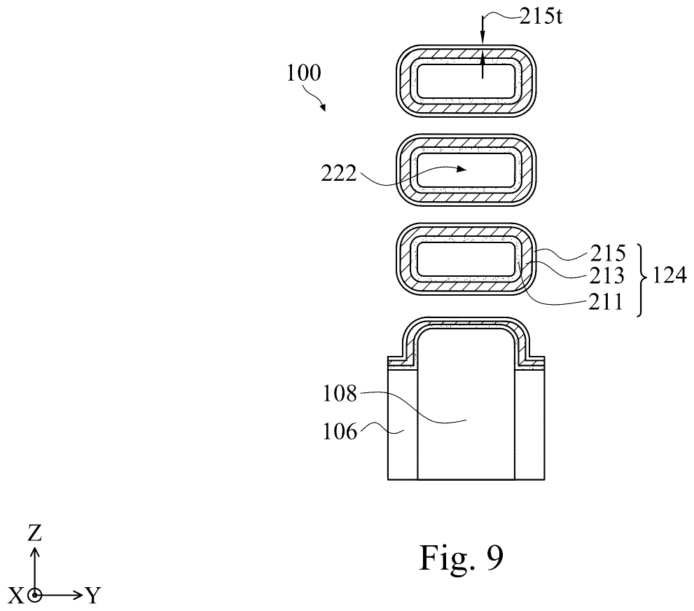

Referring to FIG. 3, in operation 350, a second high-k date dielectric layer is formed on the first high-k gate dielectric layer. The second high-k dielectric layer includes a second metal element different from the first metal element. For example, as shown in FIG. 9, second high-k dielectric layer 215 can be formed on first high-k dielectric layer 213. In some embodiments, second high-k dielectric layer 215 can be deposited on both NFET and PFET devices. In some embodiments, second high-k dielectric layer 215 can include a high-k dielectric material different from first high-k dielectric layer 213 and can have a lower dielectric constant than first high-k dielectric layer 213. In some embodiments, second high-k dielectric layer 215 can include a second metal element different from the first metal element doped in first high-k dielectric layer 213. In some embodiments, second high-k dielectric layer 215 can include Lu₂O₃, Y₂O₃, Tm₂O₃, Er₂O₃, Gd₂O₃, or other suitable transition metal oxides. In some embodiments, the second metal element in second high-k dielectric layer 215 can diffuse into first high-k dielectric layer 213 during the deposition process to form a second dopant. In some embodiments, the second metal element in second high-k dielectric layer 215 can be different from the first metal element to avoid reaching a dopant solubility limit of one metal element.

In some embodiments, second high-k dielectric layer 215 can have a thickness 215t ranging from about 1 Å to about 5 Å. In some embodiments, a ratio of thickness 213t to thickness 215t can range from about 2 to about 50. If thickness 215t is greater than about 5 Å or the ratio is less than about 2, the dielectric constant of gate dielectric layer 124 may be reduced. If thickness 215t is less than about 1 Å or the ratio is greater than about 50, the concentration of the second metal element in first high-k dielectric layer 213 may be less than about 5% and the crystallization temperature of first high-k dielectric layer 213 may not be reduced.

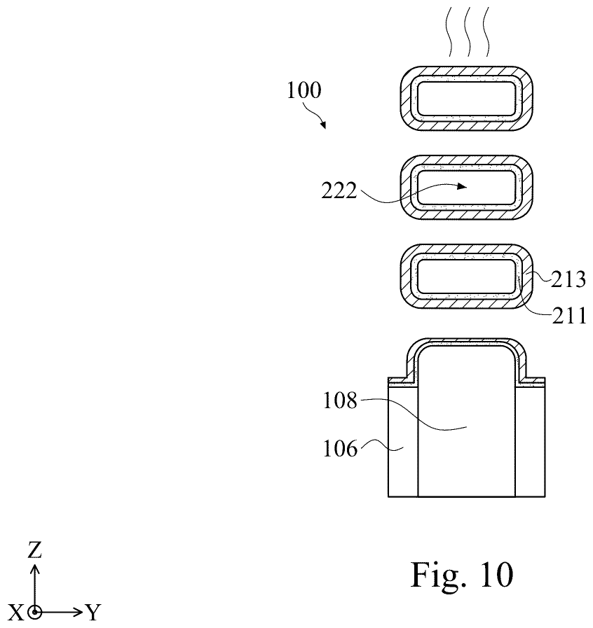

In some embodiments, the deposition of second high-k dielectric layer 215 can be followed by a post deposition anneal (PDA) process, for example, as shown in FIG. 10. In some embodiments, during the PDA process, the second metal element in second high-k dielectric layer 215 can diffuse to first high-k dielectric layer 213 to form the second dopant and can decrease the crystallization temperature of first high-k dielectric layer 213. In some embodiments, the PDA process can be performed at a temperature ranging from about 500° C. to about 700° C. to crystalize first high-k dielectric layer 213. With second high-k dielectric layer 215 and reduced annealing temperature, regrowth of interfacial layer 211 can be minimized during the PDA process. As a result, gate capacitance and device performance can be improved. In some embodiments, the PDA process can be performed in a gas environment at a pressure from about 10 mtorr to about 5 torr for a period of about 1 s to about 60 s. In some embodiments, the gas environment can include a mixture of oxygen, hydrogen, and nitrogen. In some embodiments, the crystalline high-k dielectric material in first high-k dielectric layer 213 can have a cubic crystalline phase or other crystalline phases. In some embodiments, doping first high-k dielectric layer 213 with the second dopant can increase its dielectric constant.

In some embodiments, a concentration of the second metal element in first high-k dielectric layer 213 can range from about 5% to about 25%. If the concentration of the second metal element in first high-k dielectric layer 213 is less than about 5%, the crystallization temperature of first high-k dielectric layer 213 may not be reduced. If the concentration of the second metal element in first high-k dielectric layer 213 is greater than about 25%, defects in first high-k dielectric layer 213 may increase due to higher dopant concentration than the dopant solubility limit. With the reduced crystallization temperature for first high-k dielectric layer 213, the defects at the interface of interfacial layer 211 and first high-k dielectric layer 213 can be reduced, the dopant profile change in nanostructures 222 and S/D structures 110 can be minimized, and the stress between nanostructures 222 and S/D structures 110 can be maintained.

In some embodiments, the PDA process is optional and can be omitted. In some embodiments, first high-k dielectric layer 213 can be crystallized during the deposition process of second high-k dielectric layer 215. In some embodiments, after the PDA process, second high-k dielectric layer 215 can diffuse into and intermix with first high-k dielectric layer 213, as shown in FIG. 10. In some embodiments, after the PDA process, second high-k dielectric layer 215 can be separate from first high-k dielectric layer 213, as shown in FIGS. 2 and 9.

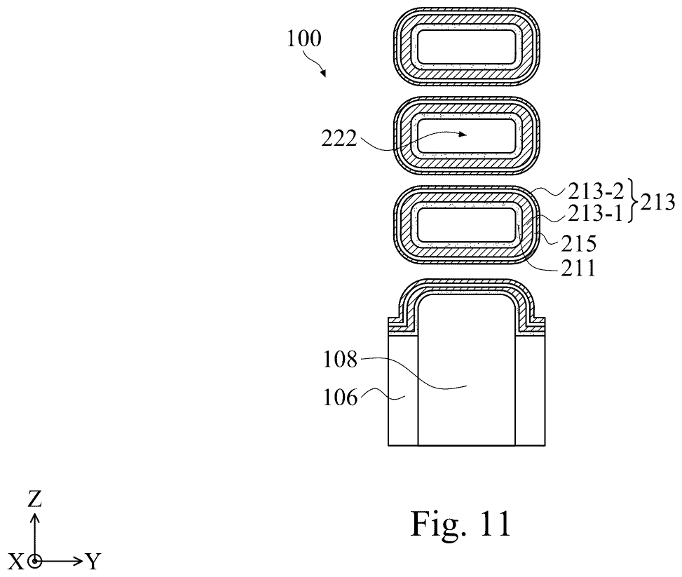

In some embodiments, as shown in FIG. 11, a first portion 213-1 of first high-k dielectric layer 213 can be deposited on interfacial layer 211. Dipole source layer 717 can be deposited on first portion 213-1 of first high-k dielectric layer 213 to dope first portion 213-1 with a first dopant and form dipoles in first portion 213-1 (not shown). After dipole source layer 717 is removed, second high-k dielectric layer 215 can be deposited on doped first portion 213-1 of first high-k dielectric layer 213. The deposition of second high-k dielectric layer 215 can be followed by deposition of a second portion 213-2 of first high-k dielectric layer 213. In some embodiments, first portion 213-1 and second portion 213-2 of first high-k dielectric layer 213 can include the same high-k dielectric material. First portion 213-1 and second portion 213-2 of first high-k dielectric layer 213 and second high-k dielectric layer 215 can be treated with a PDA process as described above. The PDA process can diffuse the second dopant in second high-k dielectric layer 215 to first high-k dielectric layer 213. The second dopant can be different from the first dopant. The second dopant can reduce the crystallization temperature of the high-k dielectric material in first high-k dielectric layer 213. In some embodiments, a total thickness of first portion 213-1 and second portion 213-2 of first high-k dielectric layer 213 can range from about 1 nm to about 5 nm.

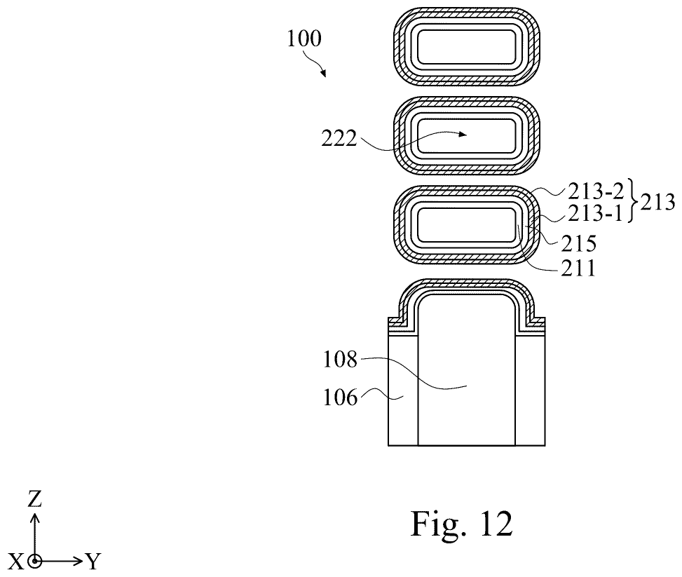

In some embodiments, as shown in FIG. 12, second high-k dielectric layer 215 having the second dopant can be deposited on interfacial layer 211. A first portion 213-1 of first high-k dielectric layer 213 can be deposited on second high-k dielectric layer 215 and can be doped with a first dopant with dipole source layer 717 to form dipoles in first portion 213-1 of first high-k dielectric layer 213. The first dopant can be different from the second dopant. A second portion 213-2 of first high-k dielectric layer 213 can be deposited on the doped first portion 213-1. In some embodiments, the first and second portions of first high-k dielectric layer 213 can include the same high-k dielectric material. In some embodiments, a total thickness of first portion 213-1 and second portion 213-2 of first high-k dielectric layer 213 can range from about 1 nm to about 5 nm. First and second high-k dielectric layer 213 and 215 can be treated with a PDA process as described above. The PDA process can diffuse the second dopant in second high-k dielectric layer 215 to first high-k dielectric layer 213 and reduce the crystallization temperature of first high-k dielectric layer 213.

The doping of first high-k dielectric layer 213 with the second dopant can be followed by formation of S/D structures 110, formation of gate structures 112, and formation of ESL 116 and ILD layer 118, which are not described in details for clarity. After these operations, semiconductor device 100 having crystalline first high-k dielectric layer 213 fabricated at a reduced crystallization temperature can be shown in FIGS. 1 and 2.

Various embodiments in the present disclosure provide example methods for forming crystalline first high-k dielectric layer 213 at a reduced crystallization temperature in semiconductor device 100. In some embodiments, nanostructures 222 can be formed on substrate 104, and interfacial layer 211 can be formed on nanostructures 222. First high-k dielectric layer 213 can be formed on interfacial layer 211 and can be doped with a first dopant to form dipoles. The first dopant can include a first metal element and can form dipoles in first high-k dielectric layer and/or at the interface between interfacial layer 211 and first high-k dielectric layer 213. Second high-k dielectric layer 215 can be formed on first high-k dielectric layer 213, and second high-k dielectric layer 215 can include a second metal element different from the first metal element. The second metal element can diffuse into first high-k dielectric layer 213 as a second dopant during a subsequent anneal process and can reduce the crystallization temperature of first high-k dielectric layer 213. In some embodiments, the crystallization temperature can be reduced to about 500° C. to about 700° C. Accordingly, first high-k dielectric layer 213 can be crystallized at a lower temperature and the thermal budget of the manufacturing process can be reduced. Additionally, the defects at the interface of interfacial layer 211 and first high-k dielectric layer 213 can be reduced, the dopant profile change in nanostructures 222 and S/D structures 110 of semiconductor device 100 can be minimized, and the stress between nanostructures 222 and S/D structures 110 can be maintained.

In some embodiments, a method includes forming a channel structure on a substrate, forming an interfacial layer on the channel structure, forming a first high-k dielectric layer on the interfacial layer, forming dipoles in the first high-k dielectric layer with a dopant, and forming a second high-k dielectric layer on the first high-k dielectric layer. The dopant includes a first metal element. The second high-k dielectric layer includes a second metal element different from the first metal element.

In some embodiments, a method includes forming first and second channel structures on a substrate, forming an interfacial layer on the first and second channel structures, forming a first dielectric layer on the interfacial layer over the first and second channel structures, forming dipoles in the first dielectric layer over the first channel structure with a first dopant, forming dipoles in the first dielectric layer over the second channel structure with a second dopant, and forming a second dielectric layer on the first dielectric layer. The first dopant includes a first metal element. The second dopant includes a second metal element different from the first metal element. The second dielectric layer includes a third metal element different from the first and second metal elements.

In some embodiments, a semiconductor structure includes a channel structure on a substrate, an interfacial layer on the channel structure, a first high-k dielectric layer on the interfacial layer over the channel structure, and a second high-k dielectric layer on the first high-k dielectric layer. The first high-k dielectric layer is doped with a dopant including a first metal element. The second high-k dielectric layer includes a second metal element different from the first metal element.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

1. A method, comprising:
forming a channel structure on a substrate;
forming an interfacial layer on the channel structure;
forming a first high-k dielectric layer on the interfacial layer;
forming dipoles in the first high-k dielectric layer with a dopant, wherein the dopant comprises a first metal element; and
forming a second high-k dielectric layer on the first high-k dielectric layer, wherein the second high-k dielectric layer comprises a second metal element different from the first metal element.

2. The method of claim 1, further comprising annealing the first and second high-k dielectric layers at a temperature from about 500° C. to about 700° C. to diffuse the second metal element into the first high-k dielectric layer.

3. The method of claim 1, further comprising forming a gate structure on the second high-k dielectric layer.

4. The method of claim 1, wherein forming the channel structure comprises forming a set of nanostructures on the substrate.

5. The method of claim 1, wherein forming the second high-k dielectric layer comprises depositing a high-k dielectric material on the first high-k dielectric layer, wherein the high-k dielectric material comprises lutetium oxide, yttrium oxide, thulium oxide, erbium oxide, or gadolinium oxide.

6. The method of claim 1, wherein the dopant comprises lutetium oxide, scandium oxide, yttrium oxide, thulium oxide, erbium oxide, gadolinium oxide, lanthanum oxide, zinc oxide, germanium oxide, aluminum oxide, titanium oxide, or vanadium oxide.

7. The method of claim 1, further comprising forming a third high-k dielectric layer on the second high-k dielectric layer, wherein the first and third high-k dielectric layers comprise a same high-k dielectric material.

8. The method of claim 1, wherein forming the dipoles in the first high-k dielectric layer comprises:
depositing a dipole source layer on the first high-k dielectric layer, wherein the dipole source layer comprises the dopant;
annealing the dipole source layer to diffuse the dopant into the first high-k dielectric layer; and
removing the dipole source layer.

9. A method, comprising:
forming first and second channel structures on a substrate;
forming an interfacial layer on the first and second channel structures;
forming a first dielectric layer on the interfacial layer over the first and second channel structures;
forming dipoles in the first dielectric layer over the first channel structure with a first dopant, wherein the first dopant comprises a first metal element;
forming dipoles in the first dielectric layer over the second channel structure with a second dopant, wherein the second dopant comprises a second metal element different from the first metal element; and
forming a second dielectric layer on the first dielectric layer, wherein the second dielectric layer comprises a third metal element different from the first and second metal elements.

10. The method of claim 9, further comprising annealing the first and second dielectric layers at a temperature from about 500° C. to about 700° C. to diffuse the third metal element into the first and second dielectric layers.

11. The method of claim 9, further comprising forming a first gate structure on the second dielectric layer over the first channel structure and a second gate structure different from the first gate structure on the second dielectric layer over the second channel structure.

12. The method of claim 9, wherein forming the first and second channel structures comprises forming first and second sets of nanostructures on the substrate.

13. The method of claim 9, wherein forming the second dielectric layer comprises depositing a high-k dielectric material on the first dielectric layer, wherein the high-k dielectric material comprises lutetium oxide, yttrium oxide, thulium oxide, erbium oxide, or gadolinium oxide.

14. The method of claim 9, further comprising forming a third dielectric layer on the second dielectric layer, wherein the first and third dielectric layers comprise a same high-k dielectric material.

15. The method of claim 9, wherein forming the dipoles in the first dielectric layer over the first and second channel structures comprises:
depositing a first dipole source layer comprising the first dopant on the first dielectric layer over the first channel structure, wherein the first dopant comprises lutetium oxide, scandium oxide, yttrium oxide, thulium oxide, erbium oxide, gadolinium oxide, or lanthanum oxide;
annealing the first dipole source layer to diffuse the first dopant into the first dielectric layer over the first channel structure;
removing the first dipole source layer;
depositing a second dipole source layer comprising the second dopant on the first dielectric layer over the second channel structure, wherein the second dopant comprises zinc oxide, germanium oxide, aluminum oxide, titanium oxide, or vanadium oxide;
annealing the second dipole source layer to diffuse the second dopant into the first dielectric layer over the second channel structure; and
removing the second dipole source layer.

16. A semiconductor device, comprising:
a channel structure on a substrate;
an interfacial layer on the channel structure;
a first high-k dielectric layer on the interfacial layer over the channel structure, wherein the first high-k dielectric layer is doped with a first dopant comprising a first metal element and a second dopant comprising a second metal element different from the first metal element; and
a second high-k dielectric layer on the first high-k dielectric layer, wherein the second high-k dielectric layer comprises the second metal element.

17. The semiconductor device of claim 16, wherein the second metal element comprises lutetium or yttrium.

18. The semiconductor device of claim 16, further comprising an additional channel structure, wherein the first high-k dielectric layer over the additional channel structure is doped with a third dopant comprising a third metal element different from the first and second metal elements.

19. The semiconductor device of claim 16, wherein the first high-k dielectric layer is crystalline and comprises the second metal element at a concentration from about 5% to about 25%.

20. The semiconductor device of claim 19, wherein a ratio of a thickness of the first high-k dielectric layer to a thickness of the second high-k dielectric layer ranges from about 2 to about 50.
